(19) United States
(12) Patent Application Publication
(10) Pub. No.: US 2012/0266960 A1
(43) Pub. Date: Oct. 25, 2012

(54) MULTI LAYER ORGANIC THIN FILM SOLAR CELL

(76) Inventors: Bin Fan, Xiamen (CN); Frank Nüesch, Wangen (CH); Roland Hany, Zurich (CH)

(21) Appl. No.: 13/497,554

(22) PCT Filed: Sep. 21, 2010
(86) PCT No.: PCT/EP10/63868

§ 371 Date: Jun. 28, 2012

(30) Foreign Application Priority Data
Sep. 24, 2009 (CH) 01475/09

(51) Int. Cl. H01L 51/46; H01L 51/48

(52) U.S. Cl. 136/263; 438/82; 257/E51.026

(57) ABSTRACT

The disclosed invention consists of high efficiency organic solar cells (0) with a multi layer structure, consisting of cathode layer (1), organic acceptor layer (2), organic donor layer (3), conductive anode layer (4) and a substrate layer (5), where an adjustment of electronic levels of separated layers is achieved by introduction of at least one intermediate matching layer (x). In conjunction with the selection of active layer (3) consisting of cyanine dyes with appropriate counterions (e.g. hexafluorophosphate), high performance organic solar cells with long lifetimes can be fabricated with a fast and simple manufacturing method.

### TECHNICAL FIELD

The present invention describes a multi layer organic thin film solar cell comprising a cathode layer, an active electron acceptor layer, an active electron donor layer, a conductive anode layer and a substrate layer that are adjacently layered one on another and a method for fabrication of multi layer organic thin film solar cells.

### STATE OF THE ART

Organic solar cells consisting of organic electronic materials are on the upswing. They bear the potential of providing cheap photovoltaic electricity.

Excitonic solar cells based on semiconducting organic small molecules and polymers in a multi layer structure are well known for a longer period of time and are considered having promising characteristics for realizing devices enabling inexpensive, large-scale solar energy conversion. These devices usually consist of a thin film of an electron donor and acceptor material, sandwiched between charge-collecting electrodes. Between one cathode layer and another conductive anode layer are sandwiched at least two layers having different electron affinities and ionization potential. The layer with the highest electron affinity and ionization potential is referred to as the acceptor layer, while the adjacent layer is referred to as the electron donor layer.

Converting light into electrical current in organic solar cells is a four stage process as depicted in the prior art FIGS. 5a and 5b. Light absorption leads to the formation of a bound electron-hole pair (exciton), which diffuses to the interface between the active layers where it is separated into free charge carriers. The free charge carriers travel by drift and diffusion between the anode and cathode and are collected as current by the electrode layers.

Excitons are formed as a result of photons that are incident on the organic semiconductors due to irradiation. If the donor material absorbs the light, the excitons diffuse to the heterojunction interface, where they can be separated into electron and holes by the electron-transfer from the Lowest Unoccupied Molecular Orbitals (LUMO) of the donor layer to the LUMO of the acceptor layer (as shown in FIG. 5b). If the acceptor layer absorbs the light, charge separation is realized by electron transfer between the corresponding HOMO levels. The drifting and diffusion of the separated charges leads to the collection of charges at the cathode layer and anode layer.

The production of organic solar cells can be performed on a large scale due to the development of flexible plastic electronics material enabling, for example, screen printing, blading and spraying of organic solar cells, which in turn lowers the production costs.

Possible industrial applications of such organic solar cells are a promising precondition for further developments.

The organic material employed in recent years led to the development of solar cells having enhanced energy conversion efficiencies, by using active layers of photoconductive dyes, as disclosed in U.S. Pat. No. 4,164,431. Although the absorption properties of used organic material layers are good, the energy conversion efficiency achieved in organic solar cells thus far remains unsatisfactory in comparison to classical semiconductor based solar cells.

As disclosed in EP1998386 the energy conversion efficiency and the carrier transportability could be improved by splitting the active layer in a plurality of stacks of electron donating and electron accepting organic semiconductor films. These films are very thin with thicknesses of 10 nm and less to provide high mobility of the separated electrons and holes after exciton separation. Due to the more complex structure of alternating lamination of different thin films of acceptor layer and active layer, the production of solar cells employing alternating lamination is more difficult. In particular, the low thickness of each thin film and the differences in thickness of p-type and n-type organic semiconductor films causes the manufacturing process to become more difficult and time consuming.

Charge injection from an electrode into an organic semiconductor is strongly dependent on the energy barrier between the electrode workfunction and the energy level of the HOMO or LUMO molecular orbitals of the active layers. This barrier is usually decreased by choosing an electrode material having a suitable work function.

Chemical doping is another way to modify the electronic structure of the interfaces and to enhance charge transfer across heterointerfaces.

According to WO9907028 the introduction of a dipolar organic monolayer as one layer of a solar cell could be used for the adjustment of the energy levels of adjacent layers. This dipolar organic monolayer also enables the transport of holes from the conductive anode layer into the donor layer whilst impeding the reverse transfer of electrons to the electrode.

There are only a few applicable molecules with sufficient dipole moment to reach the matching of the energy levels. In addition, the surface often needs to be functionalized such that a suitable anchor group of the polar molecule is attracted to the surface and the dipolar organic monolayer orients. These molecules have often to be solved in polar organic solvents, which can affect the layer underneath while manufacturing of the solar cells. Another disadvantage is the possible variation in the created layer thickness, which can result in organic molecule layers with unfeasible electrical properties, for example insulating molecule layers.

### DESCRIPTION OF THE INVENTION

The object of the present invention is to create a multi layer organic solar cell showing improved higher energy conversion efficiency by adaptation of the energy levels of adjacent arranged layers of the organic solar cell.

In a preferred embodiment of the present invention an amelioration of the charge injection contact between the electron donor layer and the conductive polymer layer leads to a higher energy conversion efficiency.

The inventive solar cell achieves these objects and is producible in a simple and fast way, by using low cost and commercially available organic raw materials leading to a flexible multi layer organic solar cell.

Another object of the subject matter of the invention is to provide a manufacturing method of the inventive solar cells with improved energy conversion efficiency, which is easy and fast to apply.

### BRIEF DESCRIPTION OF THE DRAWINGS

A preferred exemplary embodiment of the subject matter of the invention is described below in conjunction with the attached drawings.

FIG. 1 shows a schematic sectional view of one embodiment of the multilayer organic solar cell according to the present invention, while

FIG. 2 schematically shows an energy diagram of an interfacial charged double layer placed between a conductive anode layer and an active layer resulting in the bending of HOMO and LUMO levels and energy level adjustment.

FIG. 3a schematically shows a potential energy diagram of a solar cell with PEDOT:PSS and cyanine, showing a large energy difference between the HOMO levels of PEDOT:PSS and adjacent cyanine layer, while

FIG. 3b schematically shows the potential energy diagram with adjusted HOMO level of the PEDOT:PSS layer due to the insertion of the intermediate matching layer

FIG. 4 schematically shows the IV characteristic of an organic solar cell comprising an intermediate matching layer (inorganic or organic salt layer) at the conductive anode layer (PEDOT:PSS)/donor layer (CyP) interface according to FIG. 3b compared with a prior art solar cell without intermediate matching layer (dotted line).

FIG. 5a schematically shows the photo-induced charge generation and separation in a prior art organic solar cell, consisting of 1) formation of exciton; 2) exciton diffusion; 3) exciton separation; 4) drifting and diffusion of separated charges, while

FIG. 5b schematically shows the corresponding energy diagram of the prior art according to FIG. 5a.

FIG. 6 shows the chemical structures of five types of used cyanines.

### DESCRIPTION

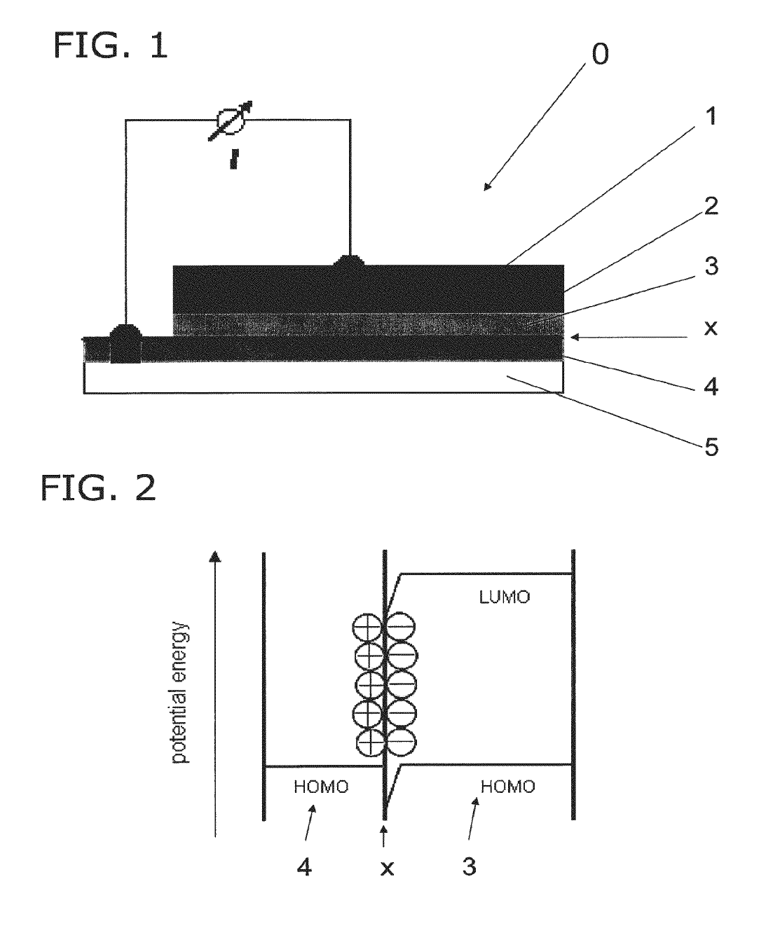

The inventive multi layer organic thin film solar cell 0 includes different adjacent separated ordered layers having different electronic properties. In the depicted multi layer architecture of FIG. 1 is a cathode layer 1 visible, to which an organic acceptor layer 2 is adjacently arranged. An organic donor layer 3 is arranged adjacent to the acceptor layer 2, followed by an organic conductive anode layer 4 and a substrate layer 5.

The cathode layer 1 is typically made of metal and therefore electrically conducting. The substrate layer 5 is also electrically conducting but has to be optical transparent, having a certain transparency of visible radiation.

The acceptor layer 2 is an n-type organic semiconductor layer and the active layer 3 is a p-type organic semiconductor layer with band gaps defined by the separation of HOMO and LUMO.

Preferred materials for the acceptor layer 2 are materials having a high electron affinity, such as fullerenes (for example C60) or mixtures of fullerenes, different fullerene derivates, cyanine dyes, anthraquinones or perylene derivatives.

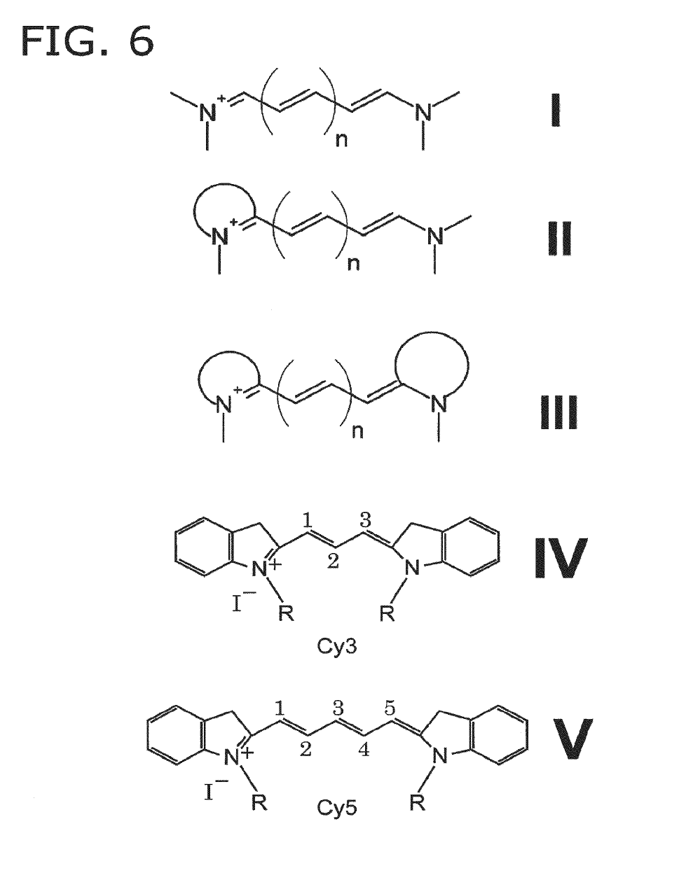

Preferred materials for active layer 3 are cyanine dyes (CyP), which are acting as electron donors. Cyanine dyes are very strong light absorbers, which have long been applied in the field of photography, acting as sensors for silver halides. Cyanine is a non-systematic name of a synthetic dye family belonging to polymethine group. Cyanines have many uses as fluorescent dyes, particularly in biomedical imaging. Depending on the structure, they cover the spectrum from IR to UV. Cyanines were first synthesized over a century ago, and there are a large number reported in the literature. Five types of used cyanines are depicted in FIG. 6, where (I) defines Streptocyanines, (II) stands for Hemicyanines and (III) shows closed chain cyanines. The Cy3 (IV) and Cy5 (V) cyanines were preferably used in the present solar cells 0. In the cyanine dyes as used the R groups are short aliphatic chains.

Cyanine dyes can be easily fabricated and purified. Their absorption range can be adjusted by changing the length of polymethine group within the molecules. Especially, their absorption can be extented into the near-infrared region. All these characteristics make CyP a suitable light absorber and, together with C60, an electron donor for organic solar cells.

The conductive anode layer 4 can be made of materials that form smooth thin films, have a high conductivity and are optical transparent such as, for example, conductive polymer poly-3,4-ethylene dioxithiophene, doped with polystyrene sulfonate, shortened as PEDOT:PSS.

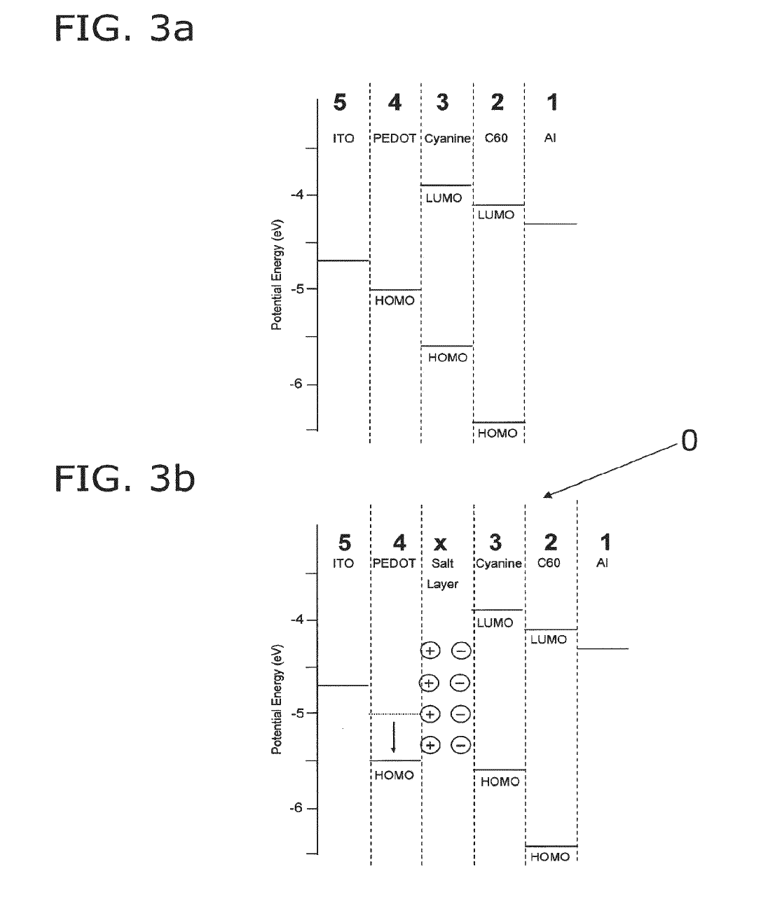

By using known materials in common organic solar cells, the HOMO level of used donor layer 3 is often not far below the HOMO level of the conductive anode layer 4. However, when using cyanine dyes as donor layer 3 and PEDOT:PSS as anode layer 4, the HOMO-HOMO energy gap is large (FIG. 3a). Moreover, the large energy difference slows down hole transfer processes between the conductive anode layer 4 and the active (cyanine) donor layer 3, leading to poor charge collection on the anode side and resulting in low fill factor and low open-circuit voltage.

### Energy Level Adjustment

To improve the charge collection properties of the present solar cell 0, an intermediate matching layer x is inserted between adjacent layers, resulting in potential energy adjustment. The insertion of the intermediate matching layer x employing a thin organic or inorganic salt layer comprising immobile cations and anions, in particular between the active layer 3 and the conductive anode layer 4, allows a fine tuning of the HOMO levels of the conductive anode layer 4 and the adjacent active layer 3, which acts as a p-type organic semiconductor.

In order to adjust the energy levels, an ultrafine salt layer x is inserted between the conductive anode layer 4, in particular a conducting polymer, and the adjacent active layer 3, for example cyanine. The different ionic affinity at the interface leads to positive and negative interfacial charges producing a potential offset. The energy offset at the interface between the conductive anode layer 4 and the active layer 3 induced by the inserted intermediate matching layer x is depicted in FIG. 2. The energy diagram of FIG. 2 schematically shows an electric potential bending offset due to the intermediate matching layer x between the active layer 3 and the conductive anode layer 4 in order to match the HOMO level of both adjacent layers 3, 4.

A great variety of organic or inorganic salts may be used and are appropriate to build the intermediate matching layer x. The manufacturing method for incorporating the thin salt layer between the conductive anode layer 4 and the active layer 3 include any of the following: spin coating, spray coating, blading, printing methods such as screen printing or inkjet printing.

In particular salts containing anions consisting of sulphate, halides, nitrate, carbonates, phosphates, borates, perchlorate or organic components consisting of sulphonic acid anions, carboxylic acid anions or sulphuric acid anions, with cations consisting of lithium, sodium, potassium, calcium, magnesium, iron, cobalt, nickel, copper, zinc, aluminium, ammonium or R4N (where R is representing any organic substituent) are useable and achieving the energy level adjustment. Typical examples for salts usable for the intermediate matching layer x include NH₄BF₄, NaBF₄, R₄NBF₄, NH₄ClO₄, NaClO₄, R₄NClO₄, LiClO₄ (here R represents any alkyl group) and also cyanine salts, which are soluble in organic solvents with low boiling point. Such organic solutions of the salts can be used for coating processes. The advantageous thicknesses of the intermediate matching layer x are in a range from at least molecular bilayer (<1 nm) up to 5 nm.

Cations and anions of the salt layer x can be chosen in such a way that the HOMO level of the conductive anode layer 4 and the one of the active layer 3 are perfectly matched. The energy level matching leads to efficient collection of positive charge carriers and therefore improves the conversion efficiency. If the intermediate matching layer x is placed between the acceptor layer 2 and donor layer 3, the ionic junction creates internal electric fields which can shift electronic orbital energy levels, impede charge generation in solar cells or separate photogenerated electrons from holes and prevent their recombination; the details of these processes, however, are only poorly understood.

### Result of a Solar Cell Including of PEDOT:PSS Layer and CyP/C60 Layers

The energy offset at the charged interface can be decreased such that the contact properties of PEDOT:PSS are drastically improved. In the CyP/C60 organic solar cells using the standard PEDOT:PSS conductive anode layer 4, inserting the intermediate matching layer x at the interface increases the open-circuit voltage, short-circuit current and fill factor, resulting in a 2.5 fold increase in power conversion efficiency under standard solar irradiation (AM 1.5 with 100 mW/cm² incident power density).

### Advantage of Cyanines as Active Layer 3:

Cyanines have previously been used by the authors as electron donors or acceptors. Efficiencies however have not been able to reach more than 1.2% so far. By doping the cyanine layer using a solid chemical doping agent and by inserting a buffer layer at the cathode interface, however, efficiencies rose to 2.6%, measured at standard solar irradiation conditions. As shown in previous work, oxidative doping of the cyanine layer greatly ameliorated all figures of merit of the device. Doping not only increased the conductivity of the cyanine layer but also ameliorated the charge injecting contact between the cyanine film and PEDOT:PSS. Despite these benefits, the lifetime of the devices was significantly reduced.

These recent results show the full potential of this class of dyes, which have the advantages of being soluble, strongly absorbing throughout the full solar irradiation spectrum and which are easy to synthesize in large quantities.

While the potential energy scheme in FIG. 3a shows the large gap between the HOMO levels of PEDOT:PSS acting as conductive anode layer 4 and the cyanine acting as active layer 3, the level matching due to the intermediate matching layer x is shown in FIG. 3b.

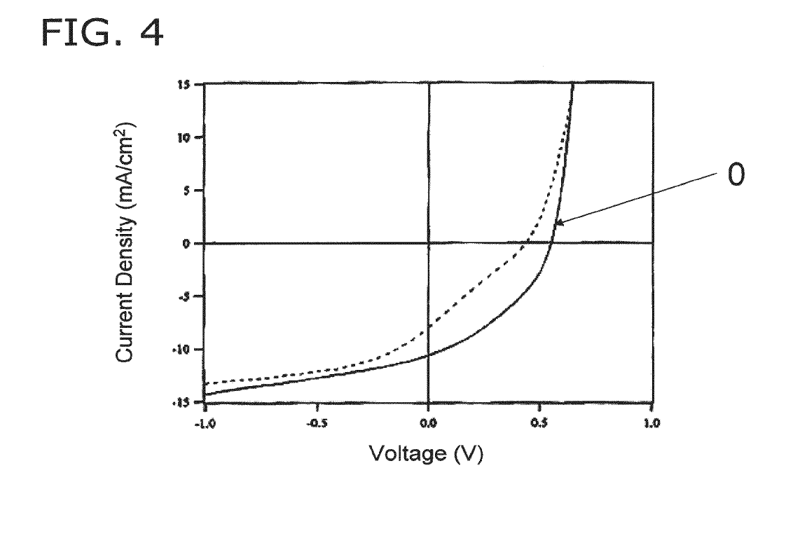

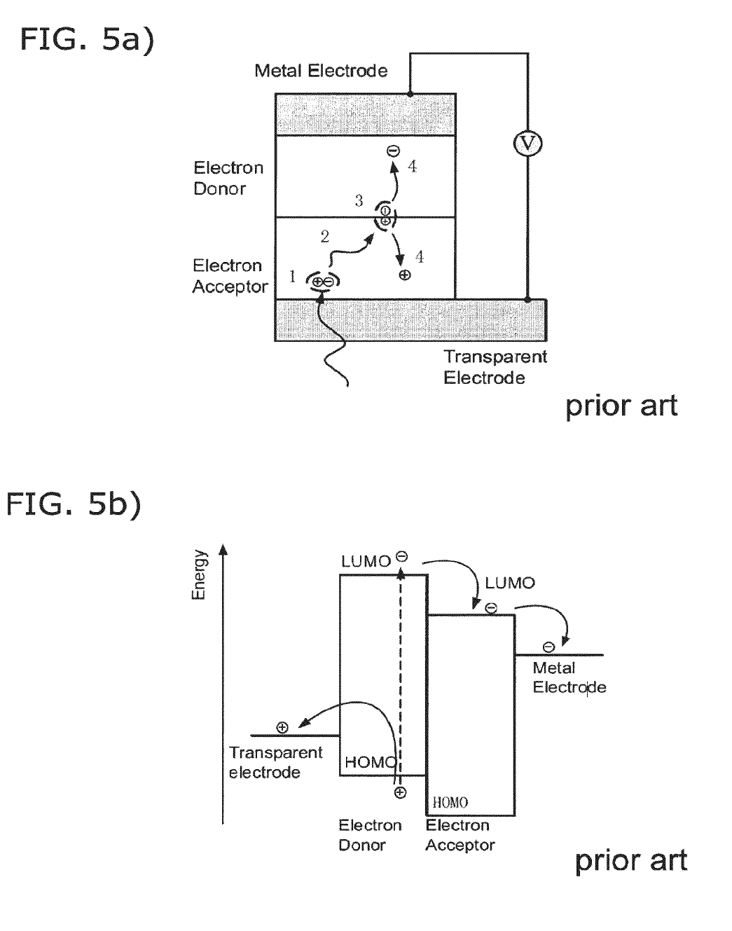

FIG. 4 schematically shows the influence on the current/voltage characteristics of an organic solar cell 0 when providing inorganic salt layer as intermediate matching layer x that is sandwiched between the PEDOT:PSS conductive layer 4 and the CyP active layer 3, as schematically shown in FIG. 3b. By using the same incident power of 100 mW/cm2, the efficiency of the “salt treated” solar cell 0 was 2.2%, instead of 0.8% of the solar cell not employing the intermediate matching layer x. Accordingly, the fill factor (FF) of the solar cell 0 with intermediate matching layer x (FF=0.37) is substantially higher than the fill factor of the untreated solar cell (FF=0.25).

### Substitute for PEDOT:PSS

In conventional organic solar cell device architecture, PEDOT:PSS is used as conductive anode layer 4 for most electron donating materials. Unfortunately this material does not provide a satisfying electrical contact to the active layer 3 employing cyanine. This deficiency is clearly visible in the fairly low fill factors of about 0.2, which lead to major losses in device performance.

To optimize the properties of the multi layer organic solar cells 0, conductive anode layers 4 featuring high work functions are preferred. Such anode layers 4 may be embodied by polyaniline shortened as PANI, doped polyaniline (−5.4 eV), doped polypyrrole (−5.5 eV), doped polythiophenes, doped poly-p-phenylenes, doped polyvinyl-carbazoles (−5.5 eV) and compounds thereof. These polymers are commercially available and can be printed in different ways, for instance with inkjet or offset printing. Measurements with a combination of PEDOT:PSS and PANI showed also good results. As mentioned above usable materials have to have a high conductivity and the generated conductive anode layer 4 has to be transparent, which is adjustable by a very thin layer.

Possible materials for the substrate layer 5 are electrically conductive and optical transparent materials like transparent conductive oxides (TCO) like Ga—In—O (5.4 eV) composite and Zn—In—O (6.1 eV) composite or Nickel oxide (NiO, 5.4 eV). Also can Carbon nanotubes, graphene, metal grids on a supporting substrate or even PEDOT:PSS on a supporting substrate be used as substrate layer 5.

Measurements showed a drastic performance increase when pure polyaniline (PANI) or compounds containing polyanyiline are used instead of PEDOT:PSS as conductive anode layer 4. That is, because the high workfunction and good conductivity of doped polyaniline is beneficial in such applications. By applying PANI, positive charges can be more easily extracted from the anode side. Experiments showed that solar cells 0 comprising a conductive anode layer 4 that employ one PEDOT:PPS and one adjacent PANI layer results in satisfying energy conversion efficiencies.

The fabrication of solar cells 0 comprising more than one intermediate matching layer x at different layer interfaces led also to improved device efficiency. Ionic charge effects due to inserting the intermediate matching layer x are not restricted to the hole-extracting anode/electron donor layer, but can more generally be used to tune energy level offsets at purely organic heterojunctions and at metal/organic heterojunctions. Therefore, intermediate matching layers x between cathode layer 1 and acceptor layer 2 and/or between acceptor layer 2 and active layer 3 and/or between conductive anode layer 4 and substrate layer 5 have a positive influence on the device efficiency.

### General Fabrication Method of Organic Solar Cell

The manufacturing method can be divided in a first part under atmospheric conditions followed by a second part under vacuum conditions.

On a clean substrate layer 5 at least one conductive anode layer 4 with a thickness of greater than 5 nm is deposited e.g., by coating. A minimum thickness of layer 4 is required to smooth the roughness of the substrate layer 5. Optionally another material for acting as another conductive anode layer 4 can be deposited subsequently.

After a drying procedure the intermediate matching layer x comprising of inorganic or organic salt solved in a solvent is coated and after drying results in a layer thickness range of at least 1 nm up to 5 nm. Covering the intermediate matching layer x, the active layer 3 is also spin coated with a resulting thickness of less than 50 nm, because the active layer 3 will otherwise absorb too much radiation.

After these manufacturing steps under ambient condition, the layered device is brought into vacuum for a period of time before a 30 nm to 100 nm thick acceptor layer 2 is deposited, e.g., by sublimation or evaporation on the active layer 3. On top of the acceptor layer 2, a thick cathode layer 1 is thermally evaporated to form the good electrically conducting cathode contact of the organic solar cell 0. For protection against degradation of the sensitive acceptor layer 2, a barrier layer comprising, e.g., Alq3 or Lithium fluoride or TiO2 or bathophenanthroline or bathocuproine with a few nanometer thickness may be evaporated or coated on the acceptor layer 2 before evaporation of the cathode layer 1. The deposition steps under vacuum condition are optionally executed while the layered device is rotated.

### Typical Fabrication Method

One experimental procedure to fabricate an ITO/PEDOT:PSS/PANI/Salt-layer/Cyanine/C60/Alq3/Al organic solar cell is described the following in detail.

1) As a substrate layer 5, an indium tin oxide (ITO) glass substrate is cleaned in ozone plasma, then placed subsequently in acetone, ethanol, and soap ultrasonic baths, and finally dried in a nitrogen flow.

2) Subsequently, a 50 nm thick layer of filtered (filter size 5 μm) poly(styrene sulfonate) doped with poly(3,4-ethylenedioxythiophene) (PEDOT:PSS) forming the conductive anode layer 4, is spin coated on top of the ITO substrate (acceleration 3000 rpm/s, maximum speed 5000 rpm, coating time 60 sec). After spin coating, the device is heated to, e.g., 120° C. for 15 minutes, before the glass/ITO/PEDOT:PSS device is then transferred into a nitrogen glovebox (water and oxygen content below 1 ppm).

3) As a second conductive anode layer 4, a 30 nm thick layer of filtered (e.g., filter size 0.45 μm) doped PANI solution (solvent 2-butanone) is spin coated (e.g., acceleration 3000 rpm/s, maximum speed 5000 rpm, coating time 60 sec) and subsequently air-dried.

4) Subsequently the intermediate matching layer x from a filtered (filter size e.g., 0.45 μm) solution of NH₄⁺BF₄⁻ in acetonitrile (0.5 mg/5 mL) is spin coated (e.g., acceleration 3000 rpm/s, maximum speed 5000 rpm, coating time 60 sec) on the second conductive anode layer 4, forming a at least 1 nm thick salt layer x.

5) Onto the intermediate matching layer x, a 30 nm thick cyanine layer (CyP,1,1′-diethyl-3,3,3′,3′-tetramethylcarbocyanine hexafluorophosphate) acting as active layer 3 is spin coated (e.g., acceleration 3000 rpm/s, maximum speed 5000 rpm, coating time 60 sec) from a filtered (filter size 0.45 μm) solution of, e.g., 100 mg cyanine dye/12 mL tetrafluoropropanol.

6) After the preceding steps the device is kept in vacuum (e.g., ˜3×10⁻⁶ mbar) for at least two hours prior to the sublimation of a 40 nm thick layer of C₆₀ acting as the acceptor layer 2 on top of the active layer 3.

7) For protection of the C₆₀, an approx. 2.5 nm thick barrier layer of Alq₃ is sublimated onto the acceptor layer 2.

8) Finally a thick cathode layer 1 of at least, e.g., 60 nm of aluminium is thermally evaporated as the top contact providing devices with different active areas.

To reach homogenous vacuum deposition results the devices are rotated (2 rpm) during vacuum deposition.

### LIST OF REFERENCE NUMERALS

0 organic solar cell
1 cathode layer
2 (organic) acceptor layer
3 (organic) donor layer
4 conductive anode layer
5 substrate layer
x intermediate matching layer

1. Multi layer organic thin film solar cell (0)
comprising a cathode layer (1), an acceptor layer (2), a donor layer (3), a conductive anode layer (4) and a substrate layer (5) that are adjacently layered one on another in the respective order, where at least one organic or inorganic intermediate matching layer (x) is arranged at heterojunction interfaces between at least two adjacently arranged layers (1, 2, 3, 4, 5),
characterized in that
the intermediate matching layer (x) comprises inorganic salt or organic salt, in particular any salt of the following group: NH₄BF₄, NaClO₄, LiClO₄, NaBF₄, R₄NBF₄, NH₄ClO₄, R₄NClO₄ (here R represents any alkyl group) and also cyanine salts.

2. Multi layer organic thin film solar cell (0) according to claim 1, characterized in that the intermediate matching layer (x) comprises salts containing anions consisting of sulphate, halides, nitrate, carbonates, phosphates, borates, perchlorate or organic components consisting of sulphonic acid anions, carboxylic acid anions or sulphuric acid anions, with cations consisting of lithium, sodium, potassium, calcium, magnesium, iron, cobalt, nickel, copper, zinc, aluminium, ammonium or R4N (where R is representing any organic substituent).

3. Multi layer organic thin film solar cell (0) according to claim 1, characterized in that the thickness of the intermediate matching layer (x) at least corresponds to the thickness of a bimonolayer.

4. Multi layer organic thin film solar cell (0) according to claim 1, characterized in that the thickness of the intermediate matching layer (x) is in a range between one and five nanometer.

5. Multi layer organic thin film solar cell (0) according to claim 1, characterized in that the conductive anode layer (4) comprises at least one of the following materials: PEDOT:PSS, doped polyaniline, doped polypyrrole, doped polythiophenes, doped poly-p-phenylenes, doped polyvinyl-carbazoles and compounds thereof.

6. Multi layer organic thin film solar cell (0) according to claim 1, characterized in that the substrate layer (5) comprises at least one of the following materials: Indium thin oxide (ITO) glass, Ga—In—O composite, Zn—In—O composite or NiO, Carbon nanotubes, graphene, metal grids on a supporting substrate, PEDOT:PSS on a supporting substrate.

7. Multi layer organic thin film solar cell (0) according to claim 1, characterized in that the acceptor layer (2) comprises organic molecules with a high electron affinity, such as fullerenes (for example C60), mixtures of fullerenes and/or different fullerene derivates and/or cyanine dyes and/or anthraquinones and/or perylene derivatives.

8. Multi layer organic thin film solar cell (0) according to claim 1, characterized in that the active layer (3) comprises cyanine dyes.

9. Multi layer organic thin film solar cell (0) according to claim 1, characterized in that the cathode layer (1) comprises Aluminium, the acceptor layer (2) comprises C₆₀ molecules, the active layer (3) comprises cyanine, the conductive anode layer (4) comprises polyaniline, PEDOT: PPS or the combination of polyaniline and PEDOT: PSS, and the intermediate matching layer (x) is inserted between the donor layer (3) and the conductive anode layer (4).

10. Multi layer organic thin film solar cell (0) according to claim 1, characterized in that the solar cell (0) comprises
a conductive anode layer (4) with a thickness of greater than 5 nm,
an adjacent intermediate matching layer (x) with a thickness of one to five nanometer, and
an adjacent active layer (3) with a thickness of less than 50 nm, followed by a 30 nm to 100 nm thick acceptor layer (2), which is covered by a cathode layer (1) thicker than 60 nm.

11. Multi layer organic thin film solar cell (0) according to claim 1, characterized in that a barrier layer, in particular consisting of Tris(8-hydroxyquinolinato)aluminium (Alq3) or Lithium fluoride (LiF), is applied between the acceptor layer (2) and the cathode layer (1).

12. Method for fabrication of multi layer organic thin film solar cells (0) according to one of the preceding claims,
characterized in
subsequent coating processes:
a) coating of conductive anode layer (4) on the substrate layer (5), followed by subsequent
b) coating of the intermediate matching layer (x) comprising inorganic salt or organic salt on the conductive anode layer (4), followed by subsequent
c) coating of the active layer (3) covering the intermediate matching layer (x), followed by d) deposition of the acceptor layer (2) onto the active layer (3) followed by e) deposition of the cathode layer (1). 13. Method for fabrication of multi layer organic thin film solar cells (0) according to Claim 12, characterized in that the coating process steps a), b) and c) are carried out under ambient conditions, while the coating process steps d) and e) are carried out under vacuum conditions. 14. Method for fabrication of multi layer organic thin film solar cells (0) according to one of the Claims 12 or 13, characterized in that the coating step b) can be applied following coating step c) and/or coating step d).
